(19) United States
(12) Patent Application Publication
(10) Pub. No.: US 2024/0387459 A1
(43) Pub. Date: Nov. 21, 2024

(54) THREE-DIMENSIONAL INTEGRATED CIRCUIT (3DIC) SYSTEMS WITH A HEAT SPREADER CONFIGURED AS A BACKSIDE POWER PLANE

(71) Applicant: Microsoft Technology Licensing, LLC, Redmond, WA (US)

(72) Inventors: Haohua ZHOU, Fremont, CA (US); Rahul AGARWAL, Livermore, CA (US)

(21) Appl. No.: 18/319,551

(22) Filed: May 18, 2023

(51) Int. Cl. H01L 25/065; H01L 21/56; H01L 23/00; H01L 23/31; H01L 23/49; H01L 23/492; H01L 25/00

(52) U.S. Cl. CPC H01L 25/0657; H01L 21/56; H01L 23/3185; H01L 23/49; H01L 23/4924; H01L 24/13; H01L 24/16; H01L 25/50; H01L 24/17; H01L 2224/13025; H01L 2224/16145; H01L 2224/16146; H01L 2224/16225; H01L 2224/1703; H01L 2224/17181; H01L 2225/06513; H01L 2225/06517; H01L 2225/06544; H01L 2225/06548; H01L 2225/06589

(57) ABSTRACT

Three-dimensional integrated circuit (3DIC) systems with the heat spreader configured as a backside power plane are described. An example 3DIC system includes a top die having a first set of through-silicon vias (TSVs) and a bottom die having a second set of TSVs for providing power, signal, and ground connectivity for components formed within the top die and the bottom die, respectively. The 3DIC system further includes a heat spreader, formed above the top die, which is configured to not only dissipate heat associated with the 3DIC system but also to deliver power to the top die using through-dielectric vias (TDVs). The TDVs are formed in an area surrounding both the bottom die and the top die. In addition, none of the second set of TSVs formed in the bottom die is configured to deliver power to the components formed within the top die.

### BACKGROUND

Traditional computing systems formed using silicon dies suffer from several problems. Some of these problems result from power versus performance tradeoffs and other design and semiconductor technology constraints, including thermal management. Such computing systems can include silicon dies that are stacked on top of each other that have through-silicon vias (TSVs) for interconnecting the signals and power/ground to various circuits among the stacked dies. Often TSVs formed in the bottom die are used to connect both power and ground to the dies stacked on top of the bottom die. This causes the density of such TSVs in the bottom die to go up as the size and/or the number of the stacked dies increases. That in turn increases the undesirable parasitics associated with the TSVs. In addition, TSVs require keep-out-zones around them taking up silicon area on the die. The higher density of the TSVs means that more silicon area is used up as part of the keep-out-zones' related area, preventing the use of such area for active circuitry or other components in the silicon area of the die.

Accordingly, there is a need for improved structures and methods for forming such computing systems.

### SUMMARY

In one example, the present disclosure relates to a three-dimensional integrated circuit (3DIC) system comprising a top die having a first set of through-silicon vias (TSVs) for providing power, signal, and ground connectivity for components formed within the top die. The 3DIC system may further include a bottom die having a second set of TSVs for providing power, signal, and ground connectivity for components formed within the bottom die.

The 3DIC system may further include a heat spreader formed above the top die, where the heat spreader is configured to not only dissipate heat associated with the 3DIC system but also to deliver power to the top die using through-dielectric vias (TDVs). The TDVs are formed in an area surrounding both the bottom die and the top die In addition, only a subset of the first set of TSVs formed in the top die are configured to deliver power to the components formed within the top die, and none of the second set of TSVs formed in the bottom die is configured to deliver power to the components formed within the top die.

In another example, the present disclosure relates to a method for forming a three-dimensional integrated circuit (3DIC) system. The method may include forming a first die having a first set of through-silicon vias (TSVs) for providing power, signal, and ground connectivity for components formed within the first die. The method may further include forming a second die having a second set of TSVs for providing power, signal, and ground connectivity for components formed within the bottom die.

The method may further include vertically stacking the second die on the first die. The method may further include forming a heat spreader above the second die, wherein the heat spreader is configured to not only dissipate heat associated with the 3DIC system but also to deliver power to the second die using through-dielectric vias (TDVs), where the TDVs are formed in an area surrounding both the first die and the second die, where only a subset of the first set of TSVs formed in the second die are configured to deliver power to the components formed within the second die, and where none of the second set of TSVs formed in the first die is configured to deliver power to the components formed within the second die.

In yet another example, the present disclosure relates to a three-dimensional integrated circuit (3DIC) system comprising a top die having a first set of through-silicon vias (TSVs) for providing power, signal, and ground connectivity for components formed within the top die. The 3DIC system may further include a bottom die having a second set of TSVs for providing power, signal, and ground connectivity for components formed within the bottom die, wherein the top die is vertically stacked on top of the bottom die.

The 3DIC system may further include a heat spreader formed above the top die, where the heat spreader is configured to not only dissipate heat associated with the 3DIC system but also to deliver power to the top die The heat spreader is supplied power through wirebonds external to both the top die and the bottom die. In addition, only a subset of the first set of TSVs formed in the top die are configured to deliver power to the components formed within the top die, and none of the second set of TSVs formed in the bottom die is configured to deliver power to the components formed within the top die.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

The present disclosure is illustrated by way of example and is not limited by the accompanying figures, in which like references indicate similar elements. Elements in the figures are illustrated for simplicity and clarity and have not necessarily been drawn to scale.

FIG. 1 shows a diagram of an example three-dimensional integrated circuit (3DIC) system with the heat spreader configured as a backside power plane;

FIG. 2 shows a top view of an example 3DIC system with the heat spreader configured as a backside power plane;

FIG. 3 shows a top view of an example 3DIC system with the heat spreader configured as a backside power/ground plane;

FIG. 4 shows a diagram of a heat spreader that is configured as a backside power plane being cooled using air in accordance with one example;

FIG. 5 shows a diagram of a heat spreader that is configured as a backside power/ground plane in accordance with one example;

FIG. 6 is a view of a 3DIC system with a heat spreader that is configured as a backside power plane during a formation stage;

FIG. 7 is a view of the 3DIC system with a heat spreader that is configured as a backside power plane during another formation stage;

FIG. 8 is a view of the 3DIC system with a heat spreader that is configured as a backside power plane during another formation stage;

FIG. 9 is a view of the 3DIC system with a heat spreader that is configured as a backside power plane during another formation stage;

FIG. 10 is a view of the 3DIC system with a heat spreader that is configured as a backside power plane during another formation stage;

FIG. 11 is a view of the 3DIC system with a heat spreader that is configured as a backside power plane during another formation stage;

FIG. 12 shows a diagram of an example 3DIC system with the backside power plane configured as a heat spreader with two dies connected in a face-to-face manner;

FIG. 13 shows a diagram of another example 3DIC system with the backside power plane configured as a heat spreader with two dies connected in a back-to-back manner; and

FIG. 14 shows a diagram of another example 3DIC system with the backside power plane configured as a heat spreader.

### DETAILED DESCRIPTION

Examples described in this disclosure relate to three-dimensional integrated circuit (3DIC) systems with the heat spreader configured as a backside power plane. Through-silicon vias (TSVs) are used for interconnecting the signals and power/ground to various circuits among the stacked dies corresponding to the 3DIC systems. Traditionally, the TSVs formed in the bottom die have been used to connect both power and signals to the dies stacked on top of the bottom die. This causes the density of such TSVs in the bottom die to go up as the size and/or the number of the stacked dies increases. This in turn increases the undesirable parasitic capacitance associated with the TSVs. In addition, as noted earlier, TSVs require keep-out-zones around them taking up silicon area on the die. The higher density of the TSVs means that more silicon area is used up as part of the keep-out-zones' related area, preventing the use of such area for active circuitry or other components in the silicon area of the die.

In addition, the vertical stacking of the dies increases the power density causing thermal management issues. Specifically, the management of the heat dissipated by the increased power density becomes challenging. The systems and methods described herein address these problems by making several improvements, including: (1) providing a power and/or ground plane directly on top of the top die and connecting the power and/or ground plane using through-dielectric vias (TDVs) or other arrangements described herein; (2) using TDVs for power and/or ground signals that are separate and different from the TSVs for the other signals allowing for better power distribution for the top die; and (3) configuring the top power and/or ground plane as both a power distribution network and a heat spreader. In effect, the heat spreader is used as a backside power and/or ground plane. As used herein the term “through-dielectric via” relates to a via that extends through at least one surface of a die that is parallel to a top surface or a bottom surface of the die. As used herein the term “through-silicon via” relates to a via that extends through one or more layers (e.g., metal, silicon, or dielectric) of a die, but does not extend through the surface that is parallel to a top surface or a bottom surface of even a single die. These improvements can be implemented in the context of various types of stacking arrangements, including face-to-face (F2F) stacking, face-to-back (F2B) stacking, or back-to-back (B2B) stacking.

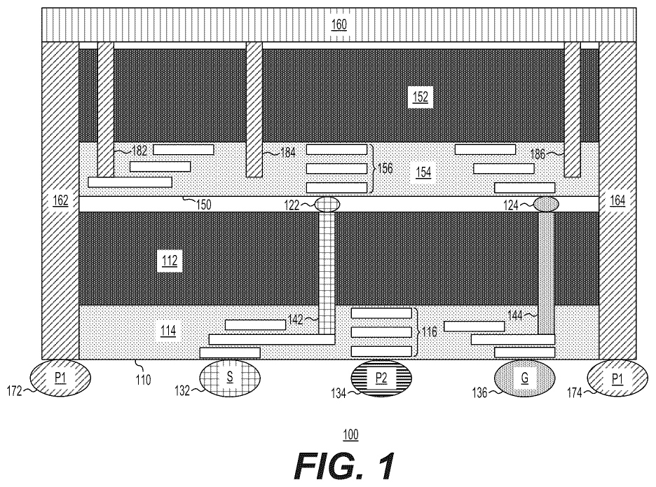

FIG. 1 shows a diagram of an example three-dimensional integrated circuit (3DIC) system 100 with the heat spreader configured as a backside power plane. In this example, 3DIC system 100 comprises two dies (die 110 and die 150) that are connected to each other in a face-to-back manner. As explained later with the other example arrangements, the dies can also be connected to each other in a face-to-face manner. In the face-to-face arrangement, the active circuitry formed on one die faces the active circuitry formed on the other die. Active circuitry may be formed on the substrate associated with each die. Each die may include both logic and memory. Processing logic may comprise one or more cores or other types of processing logic. Memory may comprise a memory array or several banks of memory arrays. The memory arrays may be implemented as static random access memory (SRAM) arrays. In addition, each SRAM may be implemented as a 2-port SRAM allowing for simultaneous read/write operations via buffers. Other memory technologies may also be used. As an example, dynamic random access memory (DRAM) or flash memory may be used. In certain examples, the bottom die may include CPUs and/or GPUs only and each of the dies stacked on top of the bottom die may be a memory die.

With continued reference to FIG. 1, die 110 includes two portions: (1) a front end of line (FEOL) portion 112 and a back end of line (BEOL) portion 114. FEOL portion 112 includes active circuitry, such as transistors, capacitors, diodes, resistors, and the like. BEOL portion 114 includes metallization layers (e.g., metal layer portions 116) and other structures (e.g., vias, insulating dielectrics, and the like) for connecting the active circuitry with bumps or pads that are external to die 110. As an example, metal layer portions 116 may be coupled to relevant bumps (e.g., signal (S), ground (G), or power bumps (P2)) via interconnection structures, such as vias. In this example, die 110 is coupled to bumps 122 and 124, which are also coupled to die 150. Similar to die 110, die 150 also includes two portions: (1) a front end of line (FEOL) portion 152 and a back end of line (BEOL) portion 154. FEOL portion 152 includes active circuitry, such as transistors, capacitors, diodes, resistors, and the like. BEOL portion 154 includes metallization layers (e.g., metal layer portions 156) and other structures (e.g., vias, insulating dielectrics, and the like) for connecting the active circuitry with bumps or pads that are external to die 150. In this example, die 150 is coupled to bumps 122 and 124, which are also coupled to die 110.

Still referring to FIG. 1, a heat spreader 160 is formed above FEOL portion 152 of die 150. Heat spreader 160 not only helps address the thermal management issues associated with vertically stacked integrated circuits but also acts as the backside power plane for delivering power to the top die in the stack. Heat spreader 160 may be formed as a copper plane. Instead of copper, aluminum or silver may also be used to form heat spreader 160. Although not shown in FIG. 1, heat spreader 160 may be electrically insulated from FEOL portion 152 using a material that is thermally conductive but electrically insulative. Heat spreader 160 is connected to TDVs 162 and 164 for supplying power to die 150. TDV 162 is coupled to a bump P1 172 and TDV 164 is coupled to a bump P1 174 for supplying power to die 150. These power bumps can be coupled to a regulated power supply. Heat spreader 160 is further coupled to TSVs 182, 184, and 186, which are configured to supply power to various components within die 150.

With continued reference to FIG. 1, die 110 is further coupled to a bump S 132 (for signals), a bump P2 134 (for power), and a bump G 136 (for ground). Die 110 further includes a TSV 142, which can be used to couple signals received via bump S 132 to die 110. This is because TSV 142 is further coupled to bump 122, which provides a connection between die 110 and die 150. In addition, die 110 includes a TSV 144, which can be used to couple ground via bump G 136 to die 150. This is because TSV 144 is further coupled to bump 124, which provides another connection between die 110 and die 150. Advantageously, the combination of heat spreader 160 and the TDVs (e.g., TDVs 162 and 164) form a better power distribution network than is feasible without the use of such a combination. Moreover, many of the TSVs that would otherwise be required for the distribution of power and/or ground to the top die (e.g., die 150) through the bottom die (e.g., bottom die 110) are not required, freeing up area within the bottom die for other components. Although FIG. 1 shows a certain number of components of 3DIC system 100 arranged in a certain manner, there could be more or fewer number of components arranged differently. As an example, the 3DIC system may include more than two dies. In addition, the dies may comprise central processing units (CPUs), application specific integrated circuits (ASICs), graphical processing units (GPUs), field programmable gate arrays (FPGAs), microcontrollers, I/O circuits, Ethernet PHYs, or other silicon IP. In addition, although FIG. 1 shows a certain number and arrangement of TDVs and TSVs that are configured to supply power to the top die, the number and arrangement of the TDVs and the TSVs may be different. Moreover, although die 110 and die 150 are shown as having a certain number of layers arranged in a certain manner, die 110 and die 150 may include additional or fewer layers arranged differently. Although FIG. 1 shows die 110 and die 150 interconnected vertically using bumps 122 and 124, die 110 and die 150 may be vertically stacked and connected to each other using different techniques. As an example, die 110 and die 150 may be bonded to each other using a wafer-to-wafer bonding technique.

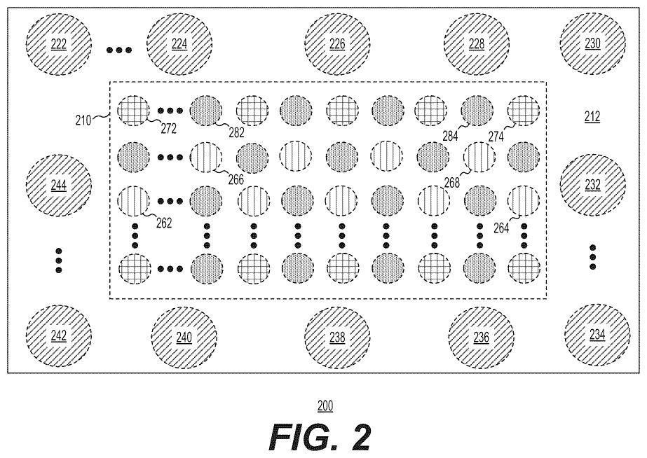

FIG. 2 shows a top view 200 of one example 3DIC system with the heat spreader configured as a backside power plane. This example relates to a system such as 3DIC system 100 of FIG. 1 but is not identical in terms of the arrangement and the placement of the TDVs and TSVs. The TDVs in this example are formed in area 212 surrounding the components formed in die 210. This example shows a cross-section view of each of TDVs 222, 224, 226, 228, 230, 232, 234, 236, 238, 240, 240, and 242 that are formed in area 212, which surrounds die 210. In this example, the TDVs are vias that extend through a surface that is parallel to a top surface of the top die (e.g., die 210, which is similar to die 150 of FIG. 1). In this example, the TDVs are coupled to bumps (e.g., bump P1 172 and bump P1 174) that are configured to supply power to the top die.

With continued reference to FIG. 2, in addition, this example shows a cross-section view of each of TSVs 262, 264, 266, 268, 272, 274, 282, and 284 that are formed as part of die 210. Unlike the TDVs, the TSVs do not extend through a surface that is parallel to the top surface of die 210. Moreover, some of the TSVs (e.g., TSVs 262, 264, 266, and 268) are coupled via the heat spreader (e.g., similar to heat spreader 160 of FIG. 1) to allow for the distribution of power through the top die (e.g., die 210). Other TSVs (e.g. TSVs 272, 274, 282, and 284) are configured to connect bumps that carry signals or bumps that are coupled to ground. Advantageously, the combination of the heat spreader and the TDVs (e.g., TDVs 222, 224, 226, 228, 230, 232, 234, 236, 238, 240, 240, and 242) form a better power distribution network than is feasible without the use of such a combination. Although FIG. 2 shows a certain number and arrangement of TDVs that are configured to supply power to the top die, the number and arrangement of the TDVs may be different. In addition, some of the TDVs may be used to provide connectivity to ground.

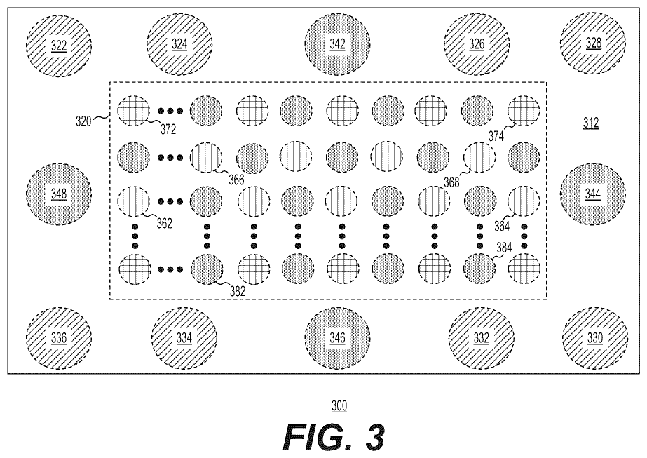

FIG. 3 shows a top view 300 of one example 3DIC system with the heat spreader configured as a backside power/ground plane. This example relates to a system such as 3DIC system 100 of FIG. 1 but is not identical in terms of the arrangement and the placement of the TDVs and TSVs. In this example, TDVs are used for both supplying power and for connections to the ground. The TDVs in this example are formed in area 312 surrounding the components formed in die 310. This example shows a cross-section view of each of TDVs 322, 324, 326, 328, 330, 332, 334, and 336 that are formed in area 312, which surrounds die 310. In this example, these TDVs are coupled to bumps (e.g., bumps similar to bump P1 172 and bump P1 174) that are configured to supply power to the top die. In addition, this example shows a cross-section view of each of TDVs 342, 344, 346, and 348 that are formed in area 312, which surrounds die 310. In this example, these TDVs are coupled to bumps that are configured to connect the ground to the top die. In this example, all of these TDVs are vias that extend through a surface that is parallel to a top surface of the top die (e.g., die 310, which is similar to die 150 of FIG. 1).

With continued reference to FIG. 3, in addition, this example shows a cross-section view of each of TSVs 362, 364, 366, 368, 372, 374, 382, and 384 that are formed as part of die 310. Unlike the TDVs, these TSVs do not extend through a surface that is parallel to the top surface of die 310. Moreover, some of the TSVs (e.g., TSVs 362, 364, 366, and 368) are coupled via the heat spreader (e.g., similar to heat spreader 160 of FIG. 1) to allow for the distribution of power through the top die (e.g., die 310). Other TSVs (e.g. TSVs 372, 374, 382, and 384) are configured to connect bumps that carry signals or bumps that are coupled to ground. Some of the TSVs are coupled via a portion of the heat spreader to allow for ground connections for the top die. Advantageously, the combination of the heat spreader and the TDVs (e.g., TDVs 322, 324, 326, 328, 330, 332, 334, and 336) form a better power/ground distribution network than is feasible without the use of such a combination. Although FIG. 3 shows a certain number and arrangement of TDVs that are configured to supply power or provide ground to the top die, the number and arrangement of the TDVs may be different.

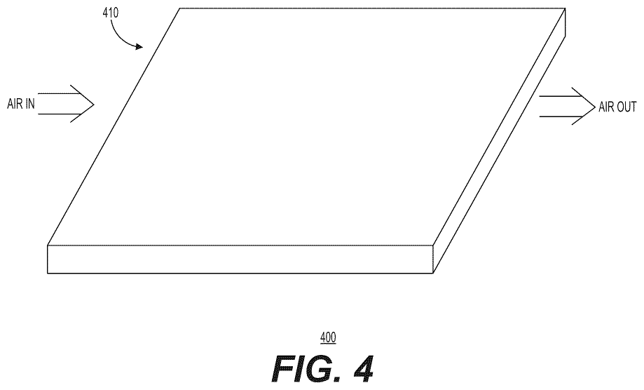

FIG. 4 shows a diagram of a heat spreader 400 that is configured as a backside power plane being cooled using air in accordance with one example. Heat spreader 400 is formed in a similar manner as heat spreader 160 of FIG. 1. Air may be moved across the surface 410 of heat spreader 400 to allow for heat to be dissipated. Although not shown in FIG. 4, additional structures, such as fins, may be coupled to the top surface 410 of heat spreader 400 to allow for further cooling. Such fin structures may be insulated from the top surface 410 of heat spreader 400 via a thermally and electrically insulating material. Although FIG. 4 shows air cooling, heat spreader 400 may also be cooled using a liquid coolant.

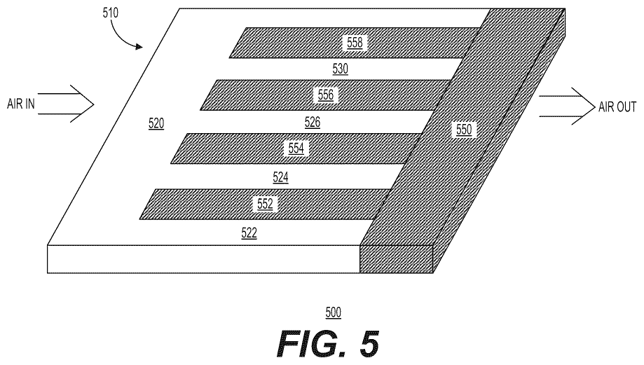

FIG. 5 shows a diagram of a heat spreader 500 that is configured as backside power/ground plane in accordance with one example. Heat spreader 500 includes both power and ground connectivity options. Air may be moved across the surface 510 of heat spreader 500 to allow for heat to be dissipated. Heat spreader 510 includes a power plane portion 520 and a ground plane portion 550. Power plane portion 520 and ground plane portion 550 are electrically insulated from each other. In this example, these two portions are organized as a combination of a base and fingers. As an example, power plane portion 520 includes fingers 522, 524, 526, 528, and 530. Ground plane portion 550 includes fingers 552, 554, 556, and 558. Other arrangements may also be used to enable heat spreader 500 to be configured as a power/ground plane for the components within at least the top die. Although not shown in FIG. 5, additional structures, such as fins, may be coupled to the top surface 510 of heat spreader 500 to allow for further cooling. Such fin structures may be insulated from the top surface of heat spreader 510 via a thermally and electrically insulating material. Although FIG. 5 shows air cooling, heat spreader 500 may also be cooled using a liquid coolant.

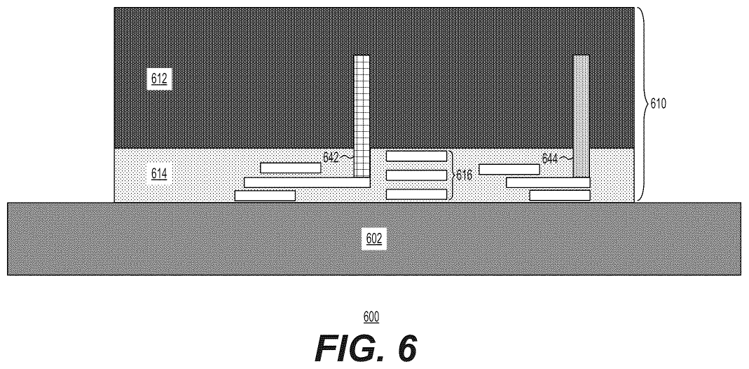

FIG. 6 is a view 600 of a 3DIC system with a heat spreader that is configured as a backside power plane during a formation stage. This formation stage shows a carrier wafer 602 with a die 610 formed on it. Die 610 is similar to bottom die 110 of FIG. 1. Die 610 includes two portions: (1) a front end of line (FEOL) portion 612 and a back end of line (BEOL) portion 614. FEOL portion 612 includes active circuitry, such as transistors, capacitors, diodes, resistors, and the like. BEOL portion 614 includes metallization layers (e.g., metal layer portions 616) and other structures (e.g., vias, insulating dielectrics, and the like) for connecting the active circuitry with bumps or pads that are external to die 610. In addition, this formation stage shows TSVs 642 and 644 formed as part of die 610. TSVs 642 and 644 may be formed using several steps, including via formation, barrier deposition into the vias, formation of a seed layer, and copper (or some other metal) plating. Although FIG. 6 shows die 610 including certain layers that are arranged in a certain manner, die 610 may include additional or fewer layers arranged differently.

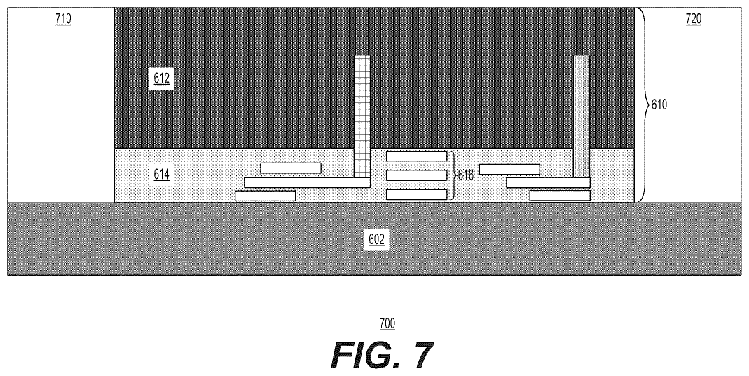

FIG. 7 is a view 700 of the 3DIC system with a heat spreader that is configured as a backside power plane during another formation stage. The same or similar components that are shown in FIG. 7 are referred to using the same reference numbers as used in FIG. 6. View 700 shows a formation stage including formation of a dielectric surrounding bottom die 610. View 700 shows in cross-section views portions 710 and 720 of the dielectric. In one example, the dielectric may be a mold compound that is formed all around die 610 and is then subsequently removed from the top surface of die 610 to allow formation of bumps or other interconnection structures for coupling with one or more additional dies that would be stacked on top of die 610. Although FIG. 7 shows die 610 including certain layers that are arranged in a certain manner, die 610 may include additional or fewer layers arranged differently. In addition, die 610 may include additional TSVs.

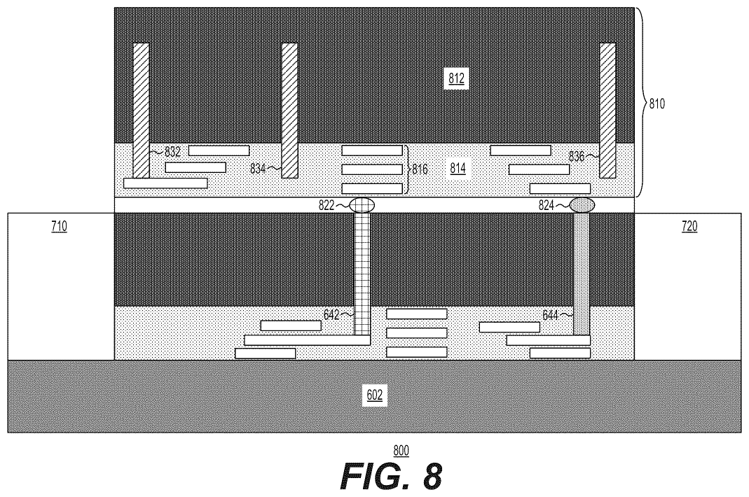

FIG. 8 is a view 800 of the 3DIC system with a heat spreader that is configured as a backside power plane during another formation stage. The same or similar components that are shown in FIG. 8 are referred to using the same reference numbers as used in FIG. 6 and FIG. 7. View 800 shows the placement of another die 810 (e.g. corresponding to die 150 of FIG. 1) on top of die 610. TSVs 642 and 644 may be exposed by grinding or otherwise removing a layer of encapsulant and then using bumps or other interconnection structures to connect the dies. Thus, in this example, prior to the placement of die 810, bumps 822 and 824 (e.g., similar to bumps 122 and 124 of FIG. 1) are formed. Bumps 822 and 824 may include metal to metal interconnection with a dielectric layer in-between. In one example, the metal to metal interconnection and the dielectric to dielectric interconnection are formed at room temperature. Die 810 may be placed using a pick-and-place tool such that interconnection structures formed within die 810 are aligned with bumps 822 and 824.

With continued reference to FIG. 8, as shown in view 800, the size of die 810 is selected such that the dielectric surrounding die 610 is not obfuscated by die 810. Die 810 (similar to die 150 of FIG. 1) also includes two portions: (1) a front end of line (FEOL) portion 812 and a back end of line (BEOL) portion 814. FEOL portion 812 includes active circuitry, such as transistors, capacitors, diodes, resistors, and the like. BEOL portion 814 includes metallization layers (e.g., metal layer portions 816) and other structures (e.g., vias, insulating dielectrics, and the like) for connecting the active circuitry with bumps or pads that are external to die 810. In this example, die 810 is coupled to bumps 822 and 824, which are also coupled to die 610. In addition, this formation stage shows TSVs 832, 834, and 836 (similar to TSVs 182, 184, and 186 of FIG. 1) formed as part of die 810. TSVs 832, 834, and 836 may be formed using several steps, including via formation, barrier deposition into the vias, formation of a seed layer, and copper (or some other metal) plating. Although FIG. 8 shows each of dies 610 and 810 including certain layers that are arranged in a certain manner, each of dies 610 and 810 may include additional or fewer layers arranged differently. In addition, although FIG. 8 shows only two stacked dies, the 3DIC system being formed may include additional vertically stacked dies. Although FIG. 8 shows die 610 and die 810 interconnected vertically using bumps 822 and 824, die 610 and die 810 may be vertically stacked and connected to each other using different techniques. As an example, die 610 and die 810 may be bonded to each other using a wafer-to-wafer bonding technique.

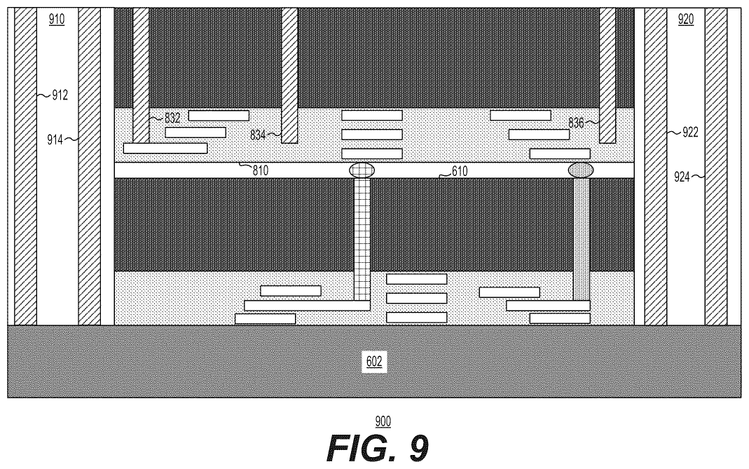

FIG. 9 is a view 900 of the 3DIC system with a heat spreader that is configured as a backside power plane during another formation stage. The same or similar components that are shown in FIG. 9 are referred to using the same reference numbers as used in FIG. 6, FIG. 7, and FIG. 8. View 900 shows the formation of a dielectric surrounding both die 610 and die 810. View 900 shows in cross-section views portions 910 and 920 of the dielectric. In one example, the dielectric may be a mold compound that is formed all around die 810 such that both die 610 and die 810 are surrounded by the mold compound. Subsequently the dielectric is removed from the top surface of die 810 to allow formation of TDVs 912, 914, 922, and 924. TDVs 912, 914, 922, and 924 may be formed using several steps, including via formation, barrier deposition into the vias, formation of a seed layer, and copper (or some other metal) plating. In addition, although FIG. 9 shows only four TDVs, as described earlier with respect to FIGS. 2 and 3, the TDVs are formed such that they surround both the bottom die and the top die.

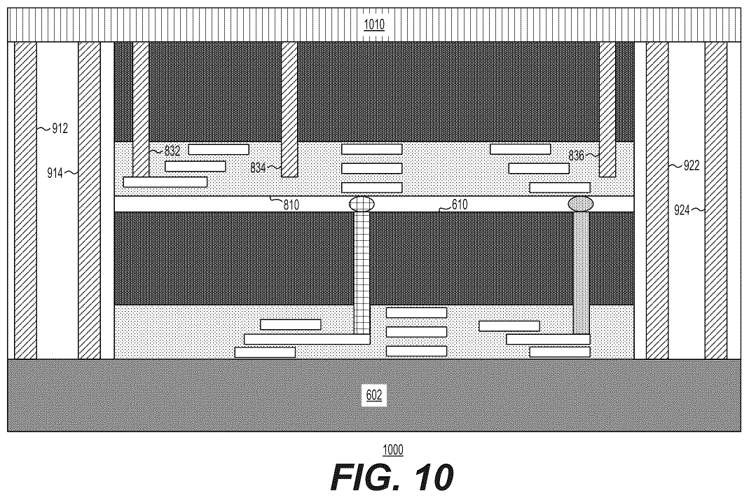

FIG. 10 is a view 1000 of the 3DIC system with a heat spreader that is configured as a backside power plane during another formation stage. The same or similar components that are shown in FIG. 10 are referred to using the same reference numbers as used in FIG. 6, FIG. 7, FIG. 8, and FIG. 9. TDVs 912, 914, 922, and 924 may be exposed by grinding or otherwise removing a layer of encapsulant or mold compound on the top surface of die 810. View 1000 shows heat spreader 1010 (similar to heat spreader 160 of FIG. 1) formed on top of die 810. Heat spreader 1010 not only helps address the thermal management issues associated with vertically stacked integrated circuits but also acts as the backside power plane for delivering power to the top die (e.g., die 810 in this example) in the stack. Although not shown in FIG. 10, heat spreader 1010 may be electrically insulated from the top surface of die 810 using a material that is thermally conductive but electrically insulative. Heat spreader 1010 is connected to TDVs 912, 914, 922, and 924 to receive power and supply the received power via TSVs 832, 834, and 826 to components within die 810. Although FIG. 10 shows each of dies 610 and 810 including certain layers that are arranged in a certain manner, each of dies 610 and 810 may include additional or fewer layers arranged differently. In addition, although FIG. 10 shows only two stacked dies, the 3DIC system being formed may include additional vertically stacked dies. Moreover, heat spreader 1010 may not only supply power but also ground to top die 810.

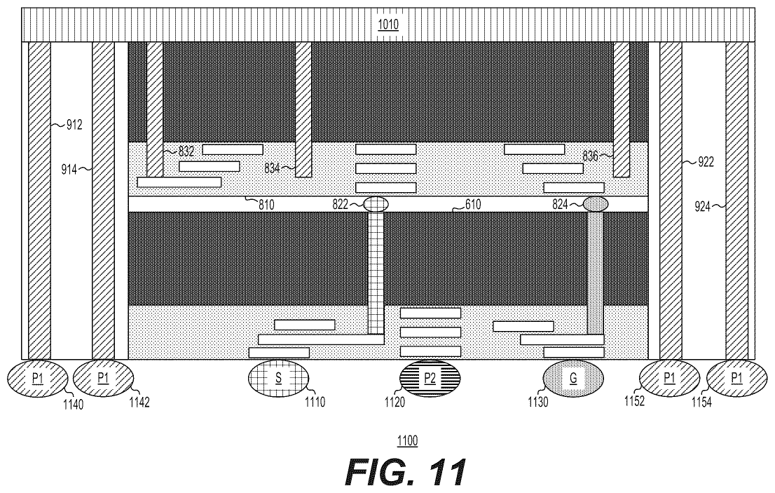

FIG. 11 is a view 1100 of the 3DIC system with a heat spreader that is configured as a backside power plane during another formation stage. The same or similar components that are shown in FIG. 11 are referred to using the same reference numbers as used in FIG. 6, FIG. 7, FIG. 8, FIG. 9, and FIG. 10. Heat spreader 1010 is connected to TDVs 912, 914, 922, and 924 for supplying power to die 810. In order to supply power to die 810 (similar to die 150 of FIG. 1), TDV 912 is coupled to a bump P1 1140, TDV 914 is coupled to a bump P1 1142, TDV 922 is coupled to a bump P1 1152, TDV 924 is coupled to a bump P1 1154. These power bumps can be coupled to a regulated power supply. Heat spreader 1010 is further coupled to TSVs 832, 834, and 836, which are configured to supply power to various components within die 810.

With continued reference to FIG. 11, die 610 is further coupled to a bump S 1110 (for signals), a bump P2 1120 (for supplying power to die 610), and a bump G 1130 (for ground). Die 610 further includes other TSVs, which can be used to couple signals received via the various bumps coupled to the TSVs. In addition, although these bumps are shown in FIG. 11 directly below die 610, some or all of these bumps can be positioned further out by using various packaging schemes, including ball grid array (BGA) packaging. Advantageously, the combination of heat spreader 1010 and the TDVs (e.g., TDVs 912, 914, 922, and 924) form a better power distribution network than is feasible without the use of such a combination. Moreover, many of the TSVs that would otherwise be required for the distribution of power and/or ground to the top die (e.g., die 810) through the bottom die (e.g., bottom die 610) are not required, freeing up area within the bottom die for other components.

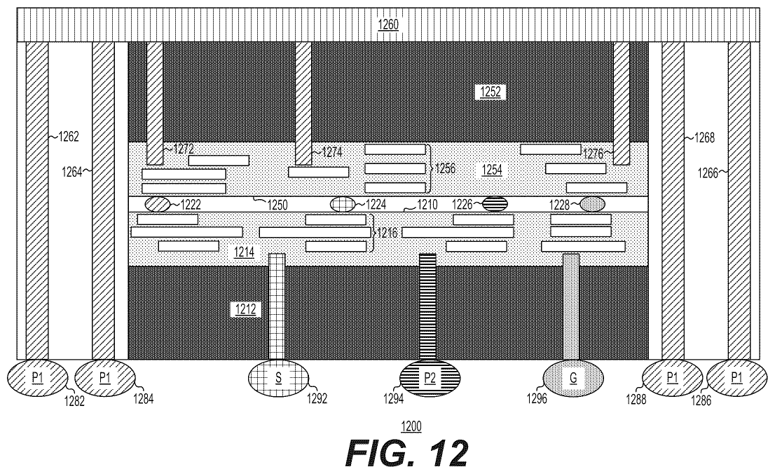

FIG. 12 shows a diagram of another example three-dimensional integrated circuit (3DIC) system 1200 with the heat spreader configured as a backside power plane. In this example, 3DIC system 1200 comprises two dies (die 1210 and die 1250) that are connected to each other in a face-to-face manner. In the face-to-face arrangement, the active circuitry formed on one die faces the active circuitry formed on the other die. Active circuitry may be formed on the substrate associated with each die. Each die may include both logic and memory. Processing logic may comprise one or more cores or other types of processing logic. Memory may comprise a memory array or several banks of memory arrays. The memory arrays may be implemented as static random access memory (SRAM) arrays. In addition, each SRAM may be implemented as a 2-port SRAM allowing for simultaneous read/write operations via buffers. Other memory technologies may also be used. As an example, dynamic random access memory (DRAM) or flash memory may be used. In certain examples, the bottom die may include CPUs and/or GPUs only and each of the dies stacked on top of the bottom die may be a memory die.

With continued reference to FIG. 12, die 1210 includes two portions: (1) a front end of line (FEOL) portion 1212 and a back end of line (BEOL) portion 1214. FEOL portion 1212 includes active circuitry, such as transistors, capacitors, diodes, resistors, and the like. BEOL portion 1214 includes metallization layers (e.g., metal layer portions 1216) and other structures (e.g., vias, insulating dielectrics, and the like) for connecting the active circuitry with bumps or pads that are external to die 1210. In this example, die 1210 is coupled to bumps 1222, 1224, 1226, and 1228, which are also coupled to die 1250. Similar to die 1210, die 1250 also includes two portions: (1) a front end of line (FEOL) portion 1252 and a back end of line (BEOL) portion 1254. FEOL portion 1252 includes active circuitry, such as transistors, capacitors, diodes, resistors, and the like. BEOL portion 1254 includes metallization layers (e.g., metal layer portions 1256) and other structures (e.g., vias, insulating dielectrics, and the like) for connecting the active circuitry with bumps or pads that are external to die 1250. In this example, die 1250 is coupled to bumps 1222, 1224, 1226, and 1228, which are also coupled to die 1210.

Still referring to FIG. 12, a heat spreader 1260 is formed above FEOL portion 1252 of die 1250. As before, heat spreader 1260 not only helps address the thermal management issues associated with vertically stacked integrated circuits but also acts as the backside power plane for delivering power to the top die in the stack. Although not shown in FIG. 12, heat spreader 1260 may be electrically insulated from FEOL portion 1252 using a material that is thermally conductive but electrically insulative. Heat spreader 1260 is connected to TDVs 1262, 1264, 1266, and 1268 for supplying power to die 1250. In order to supply power to die 1250, TDV 1262 is coupled to a bump P1 1282, TDV 1264 is coupled to a bump P1 1284, TDV 1266 is coupled to a bump P1 1286, and TDV 1268 is coupled to a bump P1 1288. These power bumps can be coupled to a regulated power supply. Heat spreader 1260 is further coupled to TSVs 1272, 1274, and 1276, which are configured to supply power to various components within die 1250.

With continued reference to FIG. 12, die 1210 is further coupled to a bump S 1292 (for signals), a bump P2 1294 (for power), and a bump G 1296 (for ground). Die 1210 further includes a TSV 1242, which can be used to couple signals received via bump S 1292 to die 1210. In addition, die 1210 includes a TSV 1244, which can be used to couple power via bump P2 1294 to die 1210. In addition, die 1210 includes a TSV 1246, which can be used to couple ground via bump G 1296 to die 1210. In addition, as needed ground connection to components within die 1250 can be provided via heat spreader 1260 or via any of the bumps (e.g., bumps 1222, 1224, 1226, and 1228) coupling die 1210 to die 1250. Advantageously, the combination of heat spreader 1260 and the TDVs (e.g., TDVs 1262, 1264, 1266, and 1268) form a better power distribution network than is feasible without the use of such a combination. Moreover, many of the TSVs that would otherwise be required for the distribution of power and/or ground to the top die (e.g., die 1250) through the bottom die (e.g., bottom die 1210) are not required, freeing up area within the bottom die for other components. Although FIG. 12 shows a certain number of components of 3DIC system 1200 arranged in a certain manner, there could be more or fewer number of components arranged differently. As an example, the 3DIC system 1200 may include more than two dies. In addition, the dies may comprise central processing units (CPUs), application specific integrated circuits (ASICs), graphical processing units (GPUs), field programmable gate arrays (FPGAs), microcontrollers, I/O circuits, Ethernet PHYs, or other silicon IP. In addition, although FIG. 12 shows a certain number and arrangement of TDVs and TSVs that are configured to supply power to the top die, the number and arrangement of the TDVs and the TSVs may be different. Moreover, although die 1210 and die 1250 are shown as having a certain number of layers arranged in a certain manner, die 1210 and die 1250 may include additional or fewer layers arranged differently. Although FIG. 12 shows die 1210 and die 1250 interconnected vertically using bumps 1222, 1224, 1226, and 1228, die 1210 and die 1250 may be vertically stacked and connected to each other using different techniques. As an example, die 1210 and die 1250 may be bonded to each other using a wafer-to-wafer bonding technique.

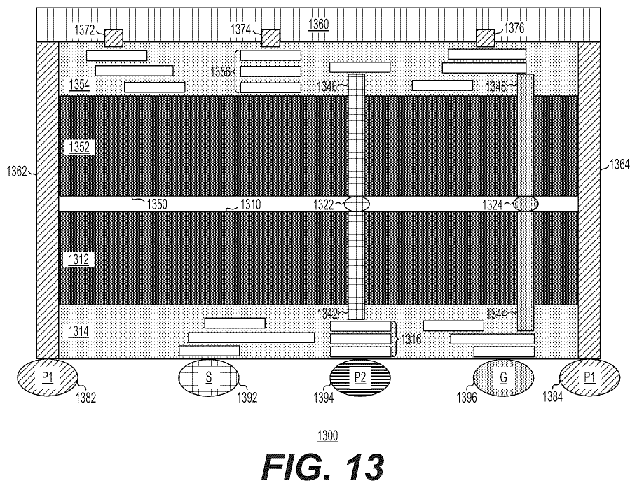

FIG. 13 shows a diagram of another example three-dimensional integrated circuit (3DIC) system 1300 with the heat spreader configured as a backside power plane. In this example, 3DIC system 1300 comprises two dies (die 1310 and die 1350) that are connected to each other in a back-to-back manner. In the back-to-back arrangement, the active circuitry formed on one die does not face the active circuitry formed on the other die. Active circuitry may be formed on the substrate associated with each die. Each die may include both logic and memory. Processing logic may comprise one or more cores or other types of processing logic. Memory may comprise a memory array or several banks of memory arrays. The memory arrays may be implemented as static random access memory (SRAM) arrays. In addition, each SRAM may be implemented as a 2-port SRAM allowing for simultaneous read/write operations via buffers. Other memory technologies may also be used. As an example, dynamic random access memory (DRAM) or flash memory may be used. In certain examples, the bottom die may include CPUs and/or GPUs only and each of the dies stacked on top of the bottom die may be a memory die.

With continued reference to FIG. 13, die 1310 includes two portions: (1) a front end of line (FEOL) portion 1312 and a back end of line (BEOL) portion 1314. FEOL portion 1312 includes active circuitry, such as transistors, capacitors, diodes, resistors, and the like. BEOL portion 1314 includes metallization layers (e.g., metal layer portions 1316) and other structures (e.g., vias, insulating dielectrics, and the like) for connecting the active circuitry with bumps or pads that are external to die 1310. In this example, die 1310 is coupled to bumps 1322 and 1324, which are also coupled to die 1350. Similar to die 1310, die 1350 also includes two portions: (1) a front end of line (FEOL) portion 1352 and a back end of line (BEOL) portion 1354. FEOL portion 1352 includes active circuitry, such as transistors, capacitors, diodes, resistors, and the like. BEOL portion 1354 includes metallization layers (e.g., metal layer portions 1356) and other structures (e.g., vias, insulating dielectrics, and the like) for connecting the active circuitry with bumps or pads that are external to die 1350. In this example, die 1350 is coupled to bumps 1322 and 1324, which are also coupled to die 1310.

Still referring to FIG. 13, a heat spreader 1360 is formed above BEOL portion 1354 of die 1350. As before, heat spreader 1360 not only helps address the thermal management issues associated with vertically stacked integrated circuits but also acts as the backside power plane for delivering power to the top die in the stack. Although not shown in FIG. 13, heat spreader 1360 may be electrically insulated from BEOL portion 1354 using a material that is thermally conductive but electrically insulative. Heat spreader 1360 is connected to TDVs 1362 and 1364 for supplying power to die 1350. In order to supply power to die 1350, TDV 1362 is coupled to a bump P1 1382 and TDV 1364 is coupled to a bump P1 1384. These power bumps can be coupled to a regulated power supply. Heat spreader 1360 is further coupled to interconnection structures 1372, 1374, and 1376, which are configured to supply power to various components within die 1350.

With continued reference to FIG. 13, die 1310 is further coupled to a bump S 1392 (for signals), a bump P2 1394 (for power), and a bump G 1396 (for ground). Die 1310 includes a TSV 1342, which can be used to couple signals via bump S 1392 to die 1310. In addition, die 1310 includes a TSV 1344, which can be used to couple ground via bump G 1396 to die 1310. In addition, as needed ground connection to components within die 1350 can be provided via heat spreader 1360 or via any of the bumps (e.g., bumps 1322 and 1324) coupling die 1310 to die 1350. Advantageously, the combination of heat spreader 1360 and the TDVs (e.g., TDVs 1362 and 1364) form a better power distribution network than is feasible without the use of such a combination. Moreover, many of the TSVs that would otherwise be required for the distribution of power and/or ground to the top die (e.g., die 1350) through the bottom die (e.g., bottom die 1310) are not required, freeing up area within the bottom die for other components. Although FIG. 13 shows a certain number of components of 3DIC system 1300 arranged in a certain manner, there could be more or fewer number of components arranged differently. As an example, the 3DIC system 1300 may include more than two dies. In addition, the dies may comprise central processing units (CPUs), application specific integrated circuits (ASICs), graphical processing units (GPUs), field programmable gate arrays (FPGAs), microcontrollers, I/O circuits, Ethernet PHYs, or other silicon IP. Moreover, although die 1310 and die 1350 are shown as having a certain number of layers arranged in a certain manner, die 1310 and die 1350 may include additional or fewer layers arranged differently. Although FIG. 13 shows die 1310 and die 1350 interconnected vertically using bumps 1322 and 1324, die 1310 and die 1350 may be vertically stacked and connected to each other using different techniques. As an example, die 1310 and die 1350 may be bonded to each other using a wafer-to-wafer bonding technique.

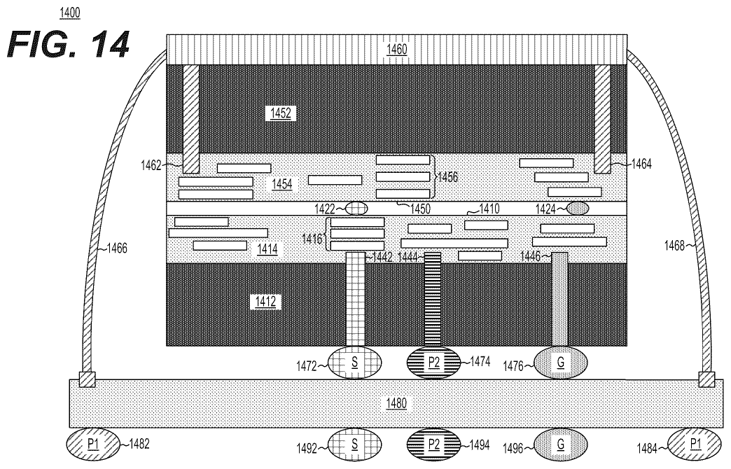

FIG. 14 shows a diagram of another example three-dimensional integrated circuit (3DIC) system 1400 with the heat spreader configured as a backside power plane. In this example, 3DIC system 1400 comprises two dies (die 1410 and die 1450) that are connected to each other in a face-to-face manner. This example is different from 3DIC system 1200 of FIG. 12 in that instead of the TDVs, wirebonds are used for providing power and/or ground to the heat spreader configured as the backside power plane for the top die. As before, in the face-to-face arrangement, the active circuitry formed on one die faces the active circuitry formed on the other die. Active circuitry may be formed on the substrate associated with each die. Each die may include both logic and memory. Processing logic may comprise one or more cores or other types of processing logic. Memory may comprise a memory array or several banks of memory arrays. The memory arrays may be implemented as static random access memory (SRAM) arrays. In addition, each SRAM may be implemented as a 2-port SRAM allowing for simultaneous read/write operations via buffers. Other memory technologies may also be used. As an example, dynamic random access memory (DRAM) or flash memory may be used. In certain examples, the bottom die may include CPUs and/or GPUs only and each of the dies stacked on top of the bottom die may be a memory die.

With continued reference to FIG. 14, die 1410 includes two portions: (1) a front end of line (FEOL) portion 1412 and a back end of line (BEOL) portion 1414. FEOL portion 1412 includes active circuitry, such as transistors, capacitors, diodes, resistors, and the like. BEOL portion 1414 includes metallization layers (e.g., metal layer portions 1416) and other structures (e.g., vias, insulating dielectrics, and the like) for connecting the active circuitry with bumps or pads that are external to die 1410. In this example, die 1410 is coupled to bumps 1422 and 1424, which are also coupled to die 1450. Similar to die 1410, die 1450 also includes two portions: (1) a front end of line (FEOL) portion 1452 and a back end of line (BEOL) portion 1454. FEOL portion 1452 includes active circuitry, such as transistors, capacitors, diodes, resistors, and the like. BEOL portion 1454 includes metallization layers (e.g., metal layer portions 1456) and other structures (e.g., vias, insulating dielectrics, and the like) for connecting the active circuitry with bumps or pads that are external to die 1450. In this example, die 1450 is coupled to bumps 1422 and 1424.

Still referring to FIG. 14, a heat spreader 1460 is formed above FEOL portion 1452 of die 1450. As before, heat spreader 1460 not only helps address the thermal management issues associated with vertically stacked integrated circuits but also acts as the backside power plane for delivering power to the top die in the stack. Although not shown in FIG. 14, heat spreader 1460 may be electrically insulated from FEOL portion 1452 using a material that is thermally conductive but electrically insulative. Heat spreader 1460 is connected to wirebonds 1466 and 1468 for receiving power and/or ground connectivity from external to die 1410 and 1450. In order to supply power to heat spreader 1460, wirebonds 1466 and 1468 are coupled to package substrate 1480. Package substrate 1480 in turn is coupled to a packaging ball P1 1482 and another packaging ball P1 1484. These packaging balls can be coupled to a regulated power supply. Heat spreader 1460 is further coupled to TSVs 1462 and 1464, which are configured to supply power to various components within die 1450.

With continued reference to FIG. 14, die 1410 is further coupled to a bump S 1472 (for signals), a bump P2 1474 (for power), and a bump G 1476 (for ground). Die 1410 further includes a TSV 1442, which can be used to couple signals received via bump S 1472 to die 1410. In addition, die 1410 includes a TSV 1444, which can be used to couple power via bump P2 1474 to die 1410. In addition, die 1410 includes a TSV 1446, which can be used to couple ground via bump G 1476 to die 1410. In addition, as needed ground connection to components within die 1450 can be provided via heat spreader 1460 or via any of the bumps (e.g., bumps 1422 and 1424) coupling die 1410 to die 1450. Package substrate 1480 is further coupled to a packaging ball S 1492 (for signals connectivity), a packaging ball P2 1494 (for power connectivity for die 1410), and a packaging ball G 1496 (for ground connectivity for either die 1410 or for both die 1410 and 1450). Advantageously, the combination of heat spreader 1460 and the wirebonds (e.g., wirebonds 1466 and 1468) form a better power distribution network than is feasible without the use of such a combination. Moreover, many of the TSVs that would otherwise be required for the distribution of power and/or ground to the top die (e.g., die 1450) through the bottom die (e.g., bottom die 1410) are not required, freeing up area within the bottom die for other components. Although FIG. 14 shows a certain number of components of 3DIC system 1400 arranged in a certain manner, there could be more or fewer number of components arranged differently. As an example, the 3DIC system 1400 may include more than two dies. In addition, the dies may comprise central processing units (CPUs), application specific integrated circuits (ASICs), graphical processing units (GPUs), field programmable gate arrays (FPGAs), microcontrollers, I/O circuits, Ethernet PHYs, or other silicon IP. In addition, although FIG. 14 shows a certain number and arrangement of TDVs and TSVs that are configured to supply power to the top die, the number and arrangement of the TDVs and the TSVs may be different. Moreover, although die 1410 and die 1450 are shown as having a certain number of layers arranged in a certain manner, die 1410 and die 1450 may include additional or fewer layers arranged differently. Although FIG. 14 shows die 1410 and die 1450 interconnected vertically using bumps 1422 and 1424, die 1410 and die 1450 may be vertically stacked and connected to each other using different techniques. As an example, die 1410 and die 1450 may be bonded to each other using a wafer-to-wafer bonding technique.

In conclusion, the present disclosure relates to a three-dimensional integrated circuit (3DIC) system comprising a top die having a first set of through-silicon vias (TSVs) for providing power, signal, and ground connectivity for components formed within the top die. The 3DIC system may further include a bottom die having a second set of TSVs for providing power, signal, and ground connectivity for components formed within the bottom die.

The 3DIC system may further include a heat spreader formed above the top die, where the heat spreader is configured to not only dissipate heat associated with the 3DIC system but also to deliver power to the top die using through-dielectric vias (TDVs). The TDVs are formed in an area surrounding both the bottom die and the top die In addition, only a subset of the first set of TSVs formed in the top die are configured to deliver power to the components formed within the top die, and none of the second set of TSVs formed in the bottom die is configured to deliver power to the components formed within the top die.

The combination of the heat spreader and the TDVs form a power distribution network. In addition, the heat spreader is further configured to provide ground connectivity to the components formed within the top die. In one example, the heat spreader comprises a planar metal structure arranged in a plane parallel to a top surface of the top die, and where the heat spreader is air cooled. In another example, the heat spreader comprises a planar metal structure arranged in a plane parallel to a top surface of the top die, and where the heat spreader is liquid cooled.

Each of the subset of the first set of TSVs formed in the top die is electrically coupled to the heat spreader, allowing for delivery of power to the components formed within the top die. The top die is connected to the bottom die via bumps, allowing for exchange of signals between the components formed within the top die and components formed within the bottom die.

In another example, the present disclosure relates to a method for forming a three-dimensional integrated circuit (3DIC) system. The method may include forming a first die having a first set of through-silicon vias (TSVs) for providing power, signal, and ground connectivity for components formed within the first die. The method may further include forming a second die having a second set of TSVs for providing power, signal, and ground connectivity for components formed within the bottom die.

The method may further include vertically stacking the second die on the first die. The method may further include forming a heat spreader above the second die, wherein the heat spreader is configured to not only dissipate heat associated with the 3DIC system but also to deliver power to the second die using through-dielectric vias (TDVs), where the TDVs are formed in an area surrounding both the first die and the second die, where only a subset of the first set of TSVs formed in the second die are configured to deliver power to the components formed within the second die, and where none of the second set of TSVs formed in the first die is configured to deliver power to the components formed within the second die.

The combination of the heat spreader and the TDVs form a power distribution network. The heat spreader is further configured to provide ground connectivity to the components formed within the top die. In one example, the heat spreader comprises a planar metal structure arranged in a plane parallel to a top surface of the top die, and where the heat spreader is air cooled. In another example, the heat spreader comprises a planar metal structure arranged in a plane parallel to a top surface of the top die, and where the heat spreader is liquid cooled.

Each of the subset of the second set of TSVs formed in the second die is electrically coupled to the heat spreader, allowing for delivery of power to the components formed within the second die. The method further includes connecting the first die to the second die via bumps, allowing for exchange of signals between the components formed within the first die and components formed within the second die.

In yet another example, the present disclosure relates to a three-dimensional integrated circuit (3DIC) system comprising a top die having a first set of through-silicon vias (TSVs) for providing power, signal, and ground connectivity for components formed within the top die. The 3DIC system may further include a bottom die having a second set of TSVs for providing power, signal, and ground connectivity for components formed within the bottom die, wherein the top die is vertically stacked on top of the bottom die.

The 3DIC system may further include a heat spreader formed above the top die, where the heat spreader is configured to not only dissipate heat associated with the 3DIC system but also to deliver power to the top die The heat spreader is supplied power through wirebonds external to both the top die and the bottom die. In addition, only a subset of the first set of TSVs formed in the top die are configured to deliver power to the components formed within the top die, and none of the second set of TSVs formed in the bottom die is configured to deliver power to the components formed within the top die.

The combination of the heat spreader and the wirebonds form a power distribution network. The heat spreader is further configured to provide ground connectivity to the components formed within the top die. In one example, the heat spreader comprises a planar metal structure arranged in a plane parallel to a top surface of the top die, and where the heat spreader is air cooled. In another example, the heat spreader comprises a planar metal structure arranged in a plane parallel to a top surface of the top die, and where the heat spreader is liquid cooled. Each of the subset of the first set of TSVs formed in the top die is electrically coupled to the heat spreader, allowing for delivery of power to the components formed within the top die.

It is to be understood that the methods, modules, and components depicted herein are merely exemplary. Alternatively, or in addition, the functionality described herein can be performed, at least in part, by one or more hardware logic components. For example, and without limitation, illustrative types of hardware logic components that can be used include Field-Programmable Gate Arrays (FPGAs), Application-Specific Integrated Circuits (ASICs), Application-Specific Standard Products (ASSPs), System-on-a-Chip systems (SOCs), Complex Programmable Logic Devices (CPLDs), etc. In an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or inter-medial components. Likewise, any two components so associated can also be viewed as being “operably connected,” or “coupled,” to each other to achieve the desired functionality.

Furthermore, those skilled in the art will recognize that boundaries between the functionality of the above described operations are merely illustrative. The functionality of multiple operations may be combined into a single operation, and/or the functionality of a single operation may be distributed in additional operations. Moreover, alternative embodiments may include multiple instances of a particular operation, and the order of operations may be altered in various other embodiments.

Although the disclosure provides specific examples, various modifications and changes can be made without departing from the scope of the disclosure as set forth in the claims below. Accordingly, the specification and figures are to be regarded in an illustrative rather than a restrictive sense, and all such modifications are intended to be included within the scope of the present disclosure. Any benefits, advantages, or solutions to problems that are described herein with regard to a specific example are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

1. A three-dimensional integrated circuit (3DIC) system comprising:
a top die having a first set of through-silicon vias (TSVs) for providing power, signal, and ground connectivity for components formed within the top die;
a bottom die having a second set of TSVs for providing power, signal, and ground connectivity for components formed within the bottom die; and
a heat spreader formed above the top die, wherein the heat spreader is configured to not only dissipate heat associated with the 3DIC system but also to deliver power to the top die using through-dielectric vias (TDVs), wherein the TDVs are formed in an area surrounding both the bottom die and the top die, wherein only a subset of the first set of TSVs formed in the top die are configured to deliver power to the components formed within the top die, and wherein none of the second set of TSVs formed in the bottom die is configured to deliver power to the components formed within the top die.

2. The 3DIC system of claim 1, wherein a combination of the heat spreader and the TDVs form a power distribution network.

3. The 3DIC system of claim 1, wherein the heat spreader is further configured to provide ground connectivity to the components formed within the top die.

4. The 3DIC system of claim 1, wherein the heat spreader comprises a planar metal structure arranged in a plane parallel to a top surface of the top die, and wherein the heat spreader is air cooled.

5. The 3DIC system of claim 1, wherein the heat spreader comprises a planar metal structure arranged in a plane parallel to a top surface of the top die, and wherein the heat spreader is liquid cooled.

6. The 3DIC system of claim 1, wherein each of the subset of the first set of TSVs formed in the top die is electrically coupled to the heat spreader, allowing for delivery of power to the components formed within the top die.

7. The 3DIC system of claim 1, wherein the top die is connected to the bottom die via bumps, allowing for exchange of signals between the components formed within the top die and components formed within the bottom die.

8. A method for forming a three-dimensional integrated circuit (3DIC) system, the method comprising:
forming a first die having a first set of through-silicon vias (TSVs) for providing power, signal, and ground connectivity for components formed within the first die;
forming a second die having a second set of TSVs for providing power, signal, and ground connectivity for components formed within the second die;
vertically stacking the second die on the first die; and
forming a heat spreader above the second die, wherein the heat spreader is configured to not only dissipate heat associated with the 3DIC system but also to deliver power to the second die using through-dielectric vias (TDVs), the TDVs are formed in an area surrounding both the first die and the second die, wherein only a subset of the second set of TSVs formed in the second die are configured to deliver power to the components formed within the second die, and wherein none of the first set of TSVs formed in the first die is configured to deliver power to the components formed within the second die.

9. The method of claim 8, wherein a combination of the heat spreader and the TDVs form a power distribution network.

10. The method of claim 8, wherein the heat spreader is further configured to provide ground connectivity to the components formed within the top die.

11. The method of claim 8, wherein the heat spreader comprises a planar metal structure arranged in a plane parallel to a top surface of the top die, and wherein the heat spreader is air cooled.

12. The method of claim 8, wherein the heat spreader comprises a planar metal structure arranged in a plane parallel to a top surface of the top die, and wherein the heat spreader is liquid cooled.

13. The method of claim 8, wherein each of the subset of the second set of TSVs formed in the second die is electrically coupled to the heat spreader, allowing for delivery of power to the components formed within the second die.

14. The method of claim 8, further comprising connecting the first die to the second die via bumps, allowing for exchange of signals between the components formed within the first die and components formed within the second die.

15. A three-dimensional integrated circuit (3DIC) system comprising:
a top die having a first set of through-silicon vias (TSVs) for providing power, signal, and ground connectivity for components formed within the top die;
a bottom die having a second set of TSVs for providing power, signal, and ground connectivity for components formed within the bottom die, wherein the top die is vertically stacked on top of the bottom die;
a heat spreader formed above the top die, wherein the heat spreader is configured to not only dissipate heat associated with the 3DIC system but also to deliver power to the top die, wherein the heat spreader is supplied power through wirebonds external to both the top die and the bottom die, wherein only a subset of the first set of TSVs formed in the top die are configured to deliver power to the components formed within the top die, and wherein none of the second set of TSVs formed in the bottom die is configured to deliver power to the components formed within the top die.

16. The 3DIC system of claim 15, wherein a combination of the heat spreader and the wirebonds form a power distribution network.

17. The 3DIC system of claim 15, wherein the heat spreader is further configured to provide ground connectivity to the components formed within the top die.

18. The 3DIC system of claim 15, wherein the heat spreader comprises a planar metal structure arranged in a plane parallel to a top surface of the top die, and wherein the heat spreader is air cooled.

19. The 3DIC system of claim 15, wherein the heat spreader comprises a planar metal structure arranged in a plane parallel to a top surface of the top die, and wherein the heat spreader is liquid cooled.

20. The 3DIC system of claim 15, wherein each of the subset of the first set of TSVs formed in the top die is electrically coupled to the heat spreader, allowing for delivery of power to the components formed within the top die.
